(19) United States
(12) Patent Application Publication
(10) Pub. No.: US 2006/0001043 A1
(43) Pub. Date: Jan. 5, 2006

(54) CMOS image sensor and fabricating method thereof

(75) Inventor: Hee Sung Shim, Seoul (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/172,169

(22) Filed: Jun. 29, 2005

(30) Foreign Application Priority Data
Jul. 1, 2004 (KR) 10-2004-0051215

(51) Int. Cl. H01L 29/732; H01L 21/8238

(52) U.S. Cl. 257/183; 257/204; 438/199

(57) ABSTRACT

A CMOS image sensor and fabricating method thereof are disclosed, by which a dark current can be reduced. The present invention includes a first conductive type semiconductor substrate divided into an active area and a field area, an STI layer formed in the field area to divide the first conductive type semiconductor substrate into active area and the field area, a second conductive type photodiode region formed in the active area of the first conductive type semiconductor substrate, a readout circuit formed in the active area of the first conductive type semiconductor substrate to read out data of the photodiode regions, and a first conductive type well formed between the second conductive type photodiode region and the STI layer.

This application claims the benefit of the Korean Patent Application No. P2004-51215 filed on Jul. 1, 2004, which is hereby incorporated by reference as if fully set forth herein.

### BACKGROUND OF THE INVENTION

1. Field of the Invention

The present invention relates to a CMOS image sensor, and more particularly, to a CMOS image sensor and fabricating method thereof. Although the present invention is suitable for a wide scope of applications, it is particularly suitable for reducing a dark current.

2. Discussion of the Related Art

Generally, a CMOS sensor fabricated using the standard CMOS process is advantageous in low power consumption, low process cost, high degree of integration and the like. Specifically, the CMOS sensor attributed to the recent advanced technology stands in the spotlight of a substitute of a charge coupled device (hereinafter abbreviated CCD) in many application fields. And, the CMOS image sensor is well known by “CMOS image sensors: Electronic Camera on a Chip” (Reference [1]) disclosed in IEEE Trans. Electron Devices, vol. 44, pp. 1689-1698, October 1997 by E. R. Fossum, “Camera-on-a-chip” (Reference [2]) disclosed in ISSCD Tech. Dig., 1996, pp. 22-25 by B. Ackland and A. Dickinsond, and “A high performance active pixel sensor with 0.18 μm CMOS color imager technology” (Reference [3]) disclosed in IEDM Tech.Dig., 2001, pp. 555-558 by S. G. Wuu, H. C. Chien, D. N. Yaung, C. H. Tseng, C. S. Wang, C. K. Chang and Y. K. Hsaio.

Yet, according to “An ultra-low dark current CMOS image sensor cell using n+ ring reset” (Reference [4]) disclosed in IEEE Electron Device Lett, vol. 23, pp. 538-540, November 2002. by H. Y. Cheng and Y. C. King, it has been reported that a dark signal level of the CMOS image sensor is higher than that of the CCD by at least 1-order.

Hence, it is an urgent problem that the dark current level should be lowered to enhance the SNR (signal-to-noise ratio) and low illumination intensity of the CMOS image sensor.

Moreover, according to “Leakage current modeling of test structures for characterization of dark current in CMOS image sensors” (Reference [5]) disclosed in IEEE Trans. Electron Devices, vol. 50, pp. 77-83, January 2003 by N. V. Loukianova, H. O. Folkerts, J. P. V. Maas, D. W. E. Verbugt, A. J. Mierop, W. Hoekstra, E. Roks and A. J. P. Theuwissen, “Empirical dark current modeling for complementary metal oxide semiconductor active pixel sensor” (Reference [6]) disclosed in Opt. Eng., vol. 41, pp. 1216-1219, June 2002 by I. Shcherback, A. Belenky and O. Yadid-Pecht, “Characterization of CMOS photo diodes for imager applications” (Reference [7]) disclosed in Proc. IEEE Workshop on CCDs and AIS, 1999, pp. 76-79 by C. C. Wang, I. L Fujimori and C. G. Sodini and “Effects of hydrogen annealing on CMOS image sensor” (Reference [8]) disclosed in Proc. IEEE Workshop on CCDs and AIS, 2001, pp. 122-124 by D. N. Yaung, S. G. Wuu, H. C. Chien, C. H. Tseng and C. S. Wang, the dark current varies according to a pixel position and time to change an output signal.

The dark current varying according to the pixel position generates a fixed pattern noise from the CMOS image sensor and the temporarily increasing dark current causes a random noise called ‘dark current shot noise’.

As the standard CMOS process is downscaled to the deep submicron regime, it becomes more difficult to fabricate a CMSO image sensor having a low-level dark current.

This is because processes for STI (shallow trench isolation), salicide, shallow source/drain junction and the like are adopted in the deep submicron CMOS to provide efficient operations of a logic or mixed-mode circuit. Hence, the most important thing in lowering the dark current of the CMOS image sensor is to understand the cause and species of the dark current.

The related art is explained with reference to the attached drawings as follows.

FIG. 1 is a layout of a 3-T CMOS image sensor according to a related art and FIG. 2 is a cross-sectional diagram of the CMOS image sensor taken along a cutting line I-I′ in FIG. 1.

Referring to FIG. 1, a unit pixel of a 3-T CMOS image sensor consists of one photodiode PD and a readout circuit. The readout circuit consists of three transistors including a rest transistor Rx for resetting photo charges collected by the photodiode PD, a drive transistor Dx playing a role as a source follower buffer amplifier and a select transistor Sx playing a role as a switch to enable addressing.

Referring to FIG. 2, a field area and an active area are defined on a semiconductor substrate 1 on which a heavily doped P type semiconductor layer and a P type epitaxial layer are sequentially stacked. An STI (shallow trench isolation) layer 6 is formed on the field area. And, a gate oxide layer 2 and a gate electrode 3 are stacked on one area of the semiconductor substrate 1 in the active area to become a gate electrode 3 of each of the above transistors.

A photodiode region (hereinafter abbreviated PD area) doped with N type impurities is formed on the active area next to the gate electrode 3, and a source and drain are provided next to both sides of the gate electrode 3, respectively.

However, the related art CMOS image sensor has the following problem.

First of all, leakage current is generated from junction leakage around the STI layer 6, off-current of the respective transistors existing in the readout circuit, dangling bonds on a surface of the semiconductor substrate 1 and the like.

Secondly, the dark current is generated from P/N junction leakage within the photodiode PD and the like.

### SUMMARY OF THE INVENTION

Accordingly, the present invention is directed to a CMOS image sensor and fabricating method thereof that substantially obviates one or more problems due to limitations and disadvantages of the related art.

An object of the present invention is to provide a CMOS image sensor and fabricating method thereof, by which a dark current can be reduced.

Another object of the present invention is to provide a CMOS image sensor and fabricating method thereof, by which the CMS image sensor below deep submicron can be fabricated by reducing a dark current.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, a CMOS image sensor according to the present invention includes a first conductive type semiconductor substrate divided into an active area and a field area, an STI layer formed in the field area to divide the first conductive type semiconductor substrate into active area and the field area, a second conductive type photodiode region formed in the active area of the first conductive type semiconductor substrate, a readout circuit formed in the active area of the first conductive type semiconductor substrate to read out data of the photodiode regions, and a first conductive type well formed between the second conductive type photodiode region and the STI layer.

In another aspect of the present invention, a CMOS image sensor includes a first conductive type semiconductor substrate divided into an active area and a field area, an STI layer formed in the field area to divide the first conductive type semiconductor substrate into active area and the field area, a second conductive type photodiode region formed in the active area of the first conductive type semiconductor substrate, a readout circuit formed in the active area of the first conductive type semiconductor substrate to read out data of the photodiode regions, and a first conductive type well formed between the STI layer and the active area of the first conductive semiconductor substrate.

In another aspect of the present invention, a method of fabricating a CMOS image sensor includes the steps of forming a trench in a field area of a first conductive type semiconductor substrate wherein an active area and the field area are defined on the first conductive type semiconductor substrate and wherein a photodiode region and a readout circuit region to read out data of the photodiode region are defined in the active area, forming a first conductive type well by implanting a first conductive type impurity into the trench neighboring the photodiode region, and forming an STI layer by filling the trench with an insulating layer.

In another aspect of the present invention, a method of fabricating a CMOS image sensor includes the steps of forming a trench in a field area of a first conductive type semiconductor substrate wherein an active area and the field area are defined on the first conductive type semiconductor substrate and wherein a photodiode region and a readout circuit region to read out data of the photodiode region are defined in the active area, forming a first conductive type well by implanting a first conductive type impurity into the trench in the vicinity of the active area, and forming an STI layer by filling the trench with an insulating layer.

In a further aspect of the present invention, a method of fabricating a CMOS image sensor includes the steps of preparing a first conductive type semiconductor substrate wherein an active area and a field area are defined on the first conductive type semiconductor substrate and wherein a photodiode region and a readout circuit region to read out data of the photodiode region are defined in the active area, forming a trench in the field area, forming a first conductive type well by implanting a first conductive type impurity into the trench in the vicinity of the active area, forming an STI layer by filling the trench with an insulating layer, implanting a second conductive type impurity into the photodiode region, and heavily implanting the first conductive type impurity into a surface of the photodiode region implanted with the second conductive type impurity.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a layout of a 3-T CMOS image sensor according to a related art;

FIG. 2 is a cross-sectional diagram of the CMOS image sensor taken along a cutting line I-I′ in FIG. 1;

FIG. 3 is a graph of Arrhenius Plot of area type N+/P junction leakage according to the present invention;

FIG. 4 is a graph of Arrhenius Plot to compare Area Type N+/P junction leakage according to the present invention to Peri (periphery) Type N+/P junction leakage;

FIG. 5 is a cross-sectional diagram of a CMOS image sensor according to a first embodiment of the present invention;

FIG. 6 is a layout for explaining a case that a P-well 7 is formed on a boundary of an STI layer 6 in a readout circuit region as well as on a boundary of a photodiode (PD) region using a first mask (Mask A) according to the present invention;

FIG. 7 is a layout for explaining a case that a P-well 7 is formed on a boundary of an STI layer 6 in a photodiode (PD) region using a second mask (Mask B) according to the present invention;

FIG. 8 is a graph exhibiting a dark signal reduction effect by a P-well according to the present invention;

FIG. 9 is a graph of a threshold voltage Vₜₕ variation followed by an STI ion implantation process applied to a channel edge area according to the present invention;

FIG. 10 is a graph of a drive current I_{dsat} variation resulting from an STI ion implantation process applied to a channel edge area according to the present invention;

FIG. 11 is a cross-sectional diagram of a CMOS image sensor according to a second embodiment of the present invention;

FIG. 12 is a simulation graph of a dark current variation of a CMOS image sensor following an integration time at 60° C. according to the present invention;

FIG. 13 is a graph of a relation between a thickness of a remaining oxide layer R_{OX} and a dark defect occurrence rate after gate spacer formation according to the present invention;

FIG. 14 is a graph of a variation of a dark signal following a photodiode surface ion implantation dose according to the present invention;

FIG. 15 is a diagram of dangling bond passivation and interface trap density reduction by hydrogen atoms on a silicon surface according to the present invention;

FIG. 16 is a graph of a dark defect variation due to gate sidewall oxidation and gate spacer under-etch according to the present invention;

FIG. 17 is a graph of a thermal cycle for forming a denuded zone according to the present invention;

FIG. 18 is a SEM picture of the denuded zone and SiOₓ precipitate generated from the thermal cycle in FIG. 17;

FIG. 19A and FIG. 19B are 10-lux and 160-lux images of a CMOS image sensor according to a related art, respectively; and

FIG. 20A and FIG. 20B are 10-lux and 160-lux images of a CMOS image sensor according to the present invention, respectively.

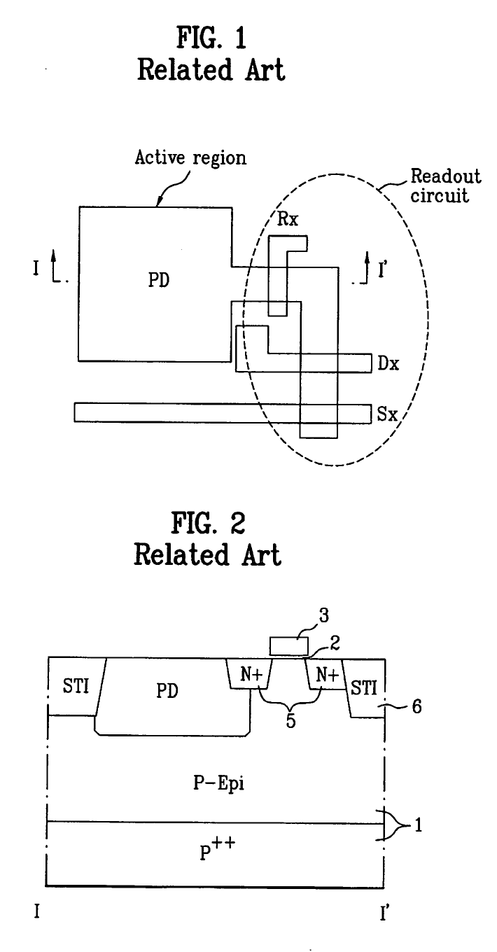

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

In a CMOS image sensor, a dark current is generated from junction leakage around an STI layer, transistor off-current existing in a readout circuit, leakage current from dangling bonds on a semiconductor layer surface, P/N junction leakage within a photodiode (PD) and the like.

Hence, the dark current generating causes are analyzed as follows.

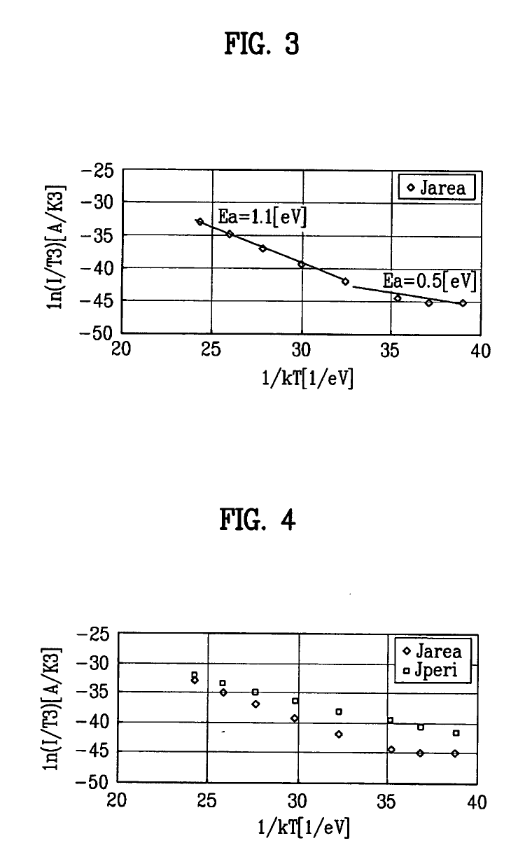

FIG. 3 shows activation energy Eₐ calculated via a slope of Arrhenius Plot from a leakage current measured per temperature at an area type N+/P junction pattern on a test pattern according to the present invention.

First of all, the reduction of the junction leakage around the STI layer is explained as follows.

A leakage current mechanism, as shown in FIG. 3, can be considered from a value of the activation energy Eₐ. Namely, the value of the activation energy Eₐ is ˜E_{g} (1.12[eV]) corresponding to a silicon band gap at high temperature or is similar to ˜E_{g}/2(0.56[eV]) at low temperature.

This means that a dark current level generated from the photodiode region depends on Diffusion Mechanism at high temperature or Recombination-Generation Mechanism of a crystalline defect function at low temperature, which is taught by “Characterization of shallow silicided junctions for sub-quarter micron ULSI technology extraction of silicidation induced Schottky contact area” disclosed in IEEE Trans. Electron Devices, vol. 47, pp. 762-767, April 2000. by H. D. Lee.

FIG. 4 is a graph of Arrhenius Plot to compare Area Type N+/P junction leakage according to the present invention to Peri (periphery) Type N+/P junction leakage, in which the leakages are measured per temperature on a test pattern.

Referring to FIG. 4, the leakage current of the Peri Type of which leakage current is mainly generated from an STI boundary (sidewall) is greater than that of the Area Type at low temperature.

From the above result, it can be known that the STI boundary as a crystalline defect area should be isolated from a photodiode depletion area to reduce the leakage current from the STI boundary of the CMOS image sensor.

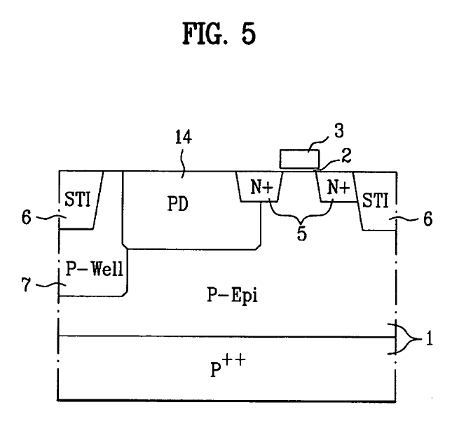

FIG. 5 is a cross-sectional diagram of a CMOS image sensor according to a first embodiment of the present invention, in which the same reference numbers of the related art CMOS image sensor in FIG. 2 are used. Besides, the same reference numbers of the related art CMOS image sensor in FIG. 2 will be used for the drawings in the following.

Referring to FIG. 5, a P-well 7 is provided between an STI layer 6 and a photodiode (PD) region 4, which is to isolate a depletion area in which electron-hole pairs are formed by the P+/N junction formation from a boundary of the STI layer 6 as a crystalline defect area.

A P-well is generally formed by diffusion through ion implantation and annealing after forming the STI layer 6. Yet, in the present invention, the P-well 7 is formed by implanting P+ type dopants before filling a trench with an insulating layer (gap-fill).

In the first embodiment of the present invention, in case of carrying out ion implantation prior to STI gap-fill, it is advantageous in selectively doping the STI boundary area using low energy.

Secondly, the transistor off-current is reduced in the following manner.

The reduction of the transistor of-current can be achieved by heavily doping a channel edge area with P type impurities or by increasing a thickness of a sidewall oxide layer before deposition of a gate electrode spacer (SiN).

The case of heavily doping a channel edge area with P type impurities is explained as follows.

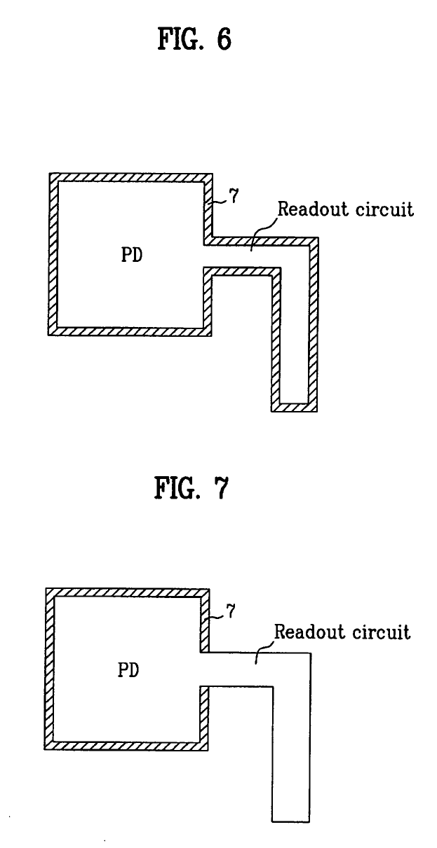

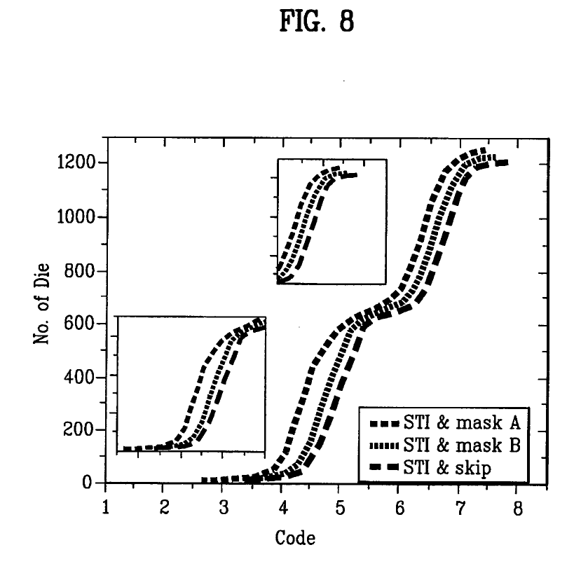

FIG. 6 is a layout for explaining a case that a P-well 7 is formed on a boundary of an STI layer 6 in a readout circuit region as well as on a boundary of a photodiode (PD) region using a first mask (Mask A) according to the present invention, FIG. 7 is a layout for explaining a case that a P-well 7 is just formed on a boundary of an STI layer 6 in a photodiode (PD) region using a second mask (Mask B) according to the present invention, and FIG. 8 is a graph exhibiting a dark signal reduction effect by a P-well according to the present invention.

According to a result of the graph shown in FIG. 8, it can be known that a dark signal is enhanced in a case (STI&Mask A, STI&Mask B) such that a P-well is formed by adding a P+STI ion implantation process prior to STI gap-fill rather than a case (STI&Skip) such that an STI layer is formed only.

This is because the number of electron-hole pairs is lowered by the thermal excitation more easily formed by the crystalline defects due to a reduction of depletion layer width extending toward an STI boundary according to a raised P+ doped density around the STI boundary.

And, it should be noted that a dark characteristic enhancing effect becomes considerable in the case such that the P-well is formed in the boundary of the STI layer 6 of the readout circuit as well as in the photodiode (PD) region like FIG. 6 rather than the case that the P-well 7 is formed in the boundary of the STI layer 6 of the photodiode (PD) region only.

This may be attributed to the of-current reduction of narrow-width NMOS transistors provided to the readout circuit.

In case of employing the STI structure for the CMOS image sensor, several wet etch processes are carried out in forming an active area or a gate electrode. By the wet etch processes, a divot appears in STI gap-fill TEOS in the vicinity of the active area to be filled with gate poly later. Namely, the STI gap-fill TEOS is overlapped with the gate poly in the divot. So, if a gate bias is applied, an electric field is concentrated on the divot due to edge geometry of the divot.

Hence, a gate voltage required for inversion in a channel edge area is reduced more than that in a channel center area, which causes a threshold voltage reduction and off-current increment of the channel edge area.

According to “Silicon processing for the VLSI era, vol. 3 The Submicron MOSFET” disclosed in vol. 3 The Submicron MOSFET, lattice Press by S. Wol, such a phenomenon is so-called “Reverse Narrow Width Effect” and gets worse in accordance with a reduction of transistor width.

Hence, in case of carrying out ion implantation on the STI boundary using the mask A (FIG. 6), P+ type doping is increased in the channel edge area of a narrow width transistor configuring the readout circuit.

Therefore, as the ‘Reverse Narrow Width Effect’ is compensated to suppress the threshold voltage reduction of transistor, the off-current is reduced.

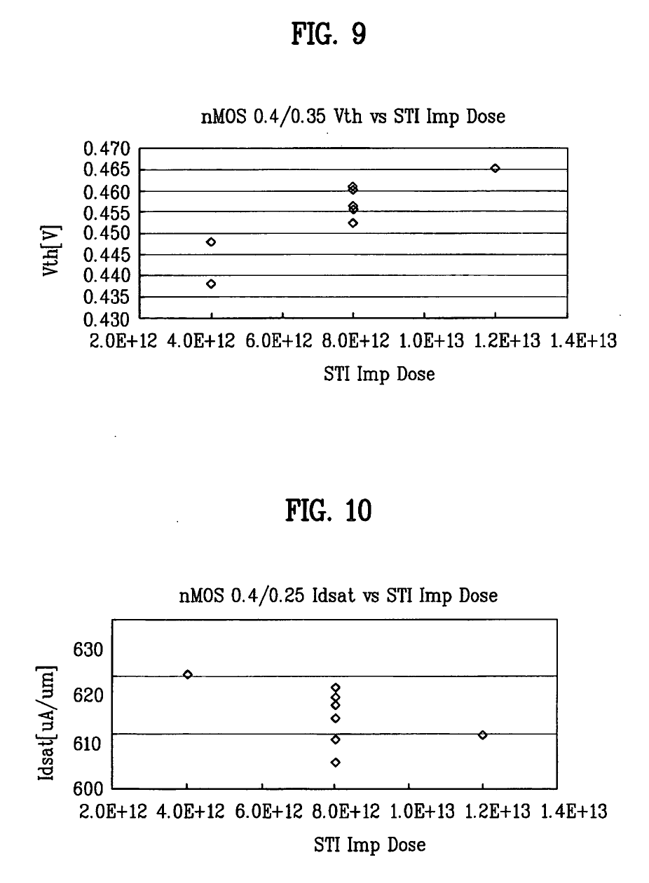

FIG. 9 is a graph of a threshold voltage Vₜₕ variation followed by an STI ion implantation process applied to a channel edge area according to the present invention, and FIG. 10 is a graph of a drive current I_{dsat} variation resulting from an STI ion implantation process applied to a channel edge area according to the present invention.

As an STI ion implant dose increases, a threshold voltage Vₜₕ of a narrow width NMOS transistor is raised but a drive current I_{dsat} is lowered.

As explained in the above description, the P-well 7 is provided to the boundary of the STI layer 6 of the readout circuit and the boundary of the STI layer 6 of the photodiode (PD) region, whereby the dark signal characteristic is more enhanced rather than the case of providing the P-well 7 to the boundary of the STI layer 6 of the photodiode (PD) region only. And, its substantial application is explained as follows.

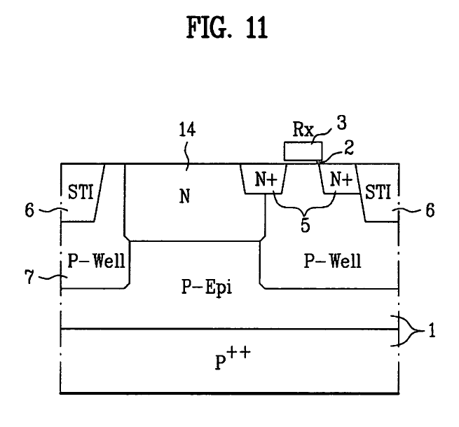

FIG. 11 is a cross-sectional diagram of a CMOS image sensor according to a second embodiment of the present invention.

Referring to FIG. 11, a P-well 7 is provided to a boundary of an STI layer 6 of a readout circuit region as well as to a boundary of the STI layer 6 of a photodiode (PD) region.

Meanwhile, the method of increasing the thickness of the sidewall oxide layer prior to the deposition of the gate poly spacer (SiN) is explained as follows.

Electrons generated from the photodiode region are delivered to the drive transistor to adjust a voltage transferred to the select transistor.

Leakage current of the respective transistors configuring the readout circuit becomes a noise source degrading the dark characteristic of the CMOS image sensor.

The leakage of the transistor is mainly caused by subthreshold leakage, gate leakage, GIDL (gate induced drain leakage) or BTBT (band to band tunneling) leakage on a source-substrate junction.

To reduce the subthreshold leakage, the doped density of the channel region is just increased. Yet, according to “A novel double offset-implanted source/drain technology for reduction of Gate-Induced Drain Leakage with 0.12 um single gate low-power SRAM device” disclosed in IEEE Trans. Electron Devices, vol. 23, pp. 719-721, December 2002 by S. H. Seo, W. S. Yang, H. S. Lee, M. S. Kim, K. O. Koh, S. H. Park and K. T. Kim and “Ultra-low leakage 0.16 um CMOS for low-standby power application” by C. C. Wu, C. H. Diaz, B. L. Lin, S. Z. Chang, C. C. Wang, J. J. Liaw, C. H. Wang, K. K. Young, K. H. Lee, B. K. Liew and J. Y. C. Sun, the increment of the doped density of the transistor channel region brings about transistor performance degradation and junction leakage increment as well.

Hence, to reduce the off-current of a unit transistor, the present invention adopts the method of increasing the thickness of the gate sidewall oxide layer prior to LDD (lightly doped drain) formation after gate poly definition.

GIDL (gate induced drain leakage) is basically attributed to an electric field between gate and drain junctions. Hence, the GIDL can be reduced by increasing the thickness of the sidewall oxide layer to locally increase the gate oxide layer thickness between the gate and the drain edge.

Table 1 shows a result from comparing drive current I_{dsat} to off-state leakage current I_{off} according to a sidewall oxide layer thickness.

TABLE 1

Sidewall oxide layer thickness

| | 60[Å] | 80[Å] |
|---|---|---|
| I_{dsat}@NMOS 20/0.25 | 562.3[μA/μm] | 544.5[μA/μm] |
| I_{dsat}@PMOS 20/0.25 | 260.9[μA/μm] | 246.9[μA/μm] |
| I_{off}@NMOS 1/0.25 | 7.2E−8[A] | 3.5E−9[A] |

Referring to Table 1, if the thickness of the sidewall oxide layer is increased by 20 Å, it can be seen that the off-current I_{off} is reduced by 1-order. Yet, current drivability, i.e., drive current I_{dsat} is reduced by 3˜5%.

Hence, it can be confirmed that the off-current can be reduced without causing a considerable loss of the current drivability in a manner of increasing the thickness of the sidewall oxide layer.

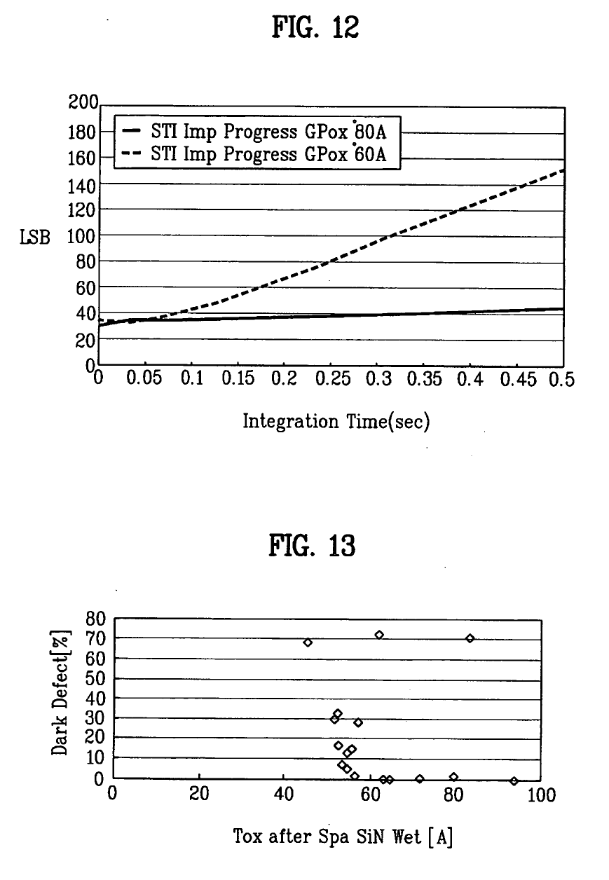

FIG. 12 is a simulation graph of a dark current variation of a CMOS image sensor following an integration time at 60° C. according to the present invention.

Referring to FIG. 12, by pixel sidewall optimization through STI sidewall implant and transistor of-state characteristics enhancement of a readout circuit through sidewall oxide layer thickness increment, it can be seen that a dark characteristic of a CMOS image sensor is considerably enhanced.

Besides, the sidewall oxide layer thickness increment can interrupt the ion damage reduction of a silicon surface.

FIG. 13 is a graph of a relation between a thickness of a remaining oxide layer Rox and a dark defect occurrence rate after gate spacer formation according to the present invention.

Referring to FIG. 13, a dark defect occurrence rate increases for a while according to a reduction of a remaining oxide layer R_{OX} and then abruptly increases after a threshold value.

Since a general CMOS logic process is used in fabricating transistors configuring a pixel readout circuit, an entire pixel including a photodiode cannot help being exposed to ion bombarding in the progress of a gate spacer RIE process. Since the remaining oxide layer R_{OX} after the gate spacer formation becomes a measure of an over-etch in performing the gate spacer RIE process, the reduction of the remaining oxide layer R_{OX} represents the ion damage increase of a photodiode surface.

Hence, the present invention proposes that the thickness of the sidewall oxide layer grown on an entire silicon surface prior to the gate spacer SiN deposition is increased. This is very effective to the ion damage reduction of the photodiode as well as to the transistor off-state characteristic enhancement.

Thirdly, the silicon surface leakage reduction method is explained as follows.

According to “Silicon processing for the VLSI era, vol. 3, The Submicron MOSFET” disclosed in “vol. 3, The Submicron MOSFET, lattice Press” by S. Wolf, a per-atomic ¼ bonding of a lattice of a silicon surface includes a dangling bond. Although the dangling bonds can be reduced by thermal oxidation performed on the silicon surface, it is unable to form a perfect Si/SiO₂ interface structure. Even if a very small ratio of atoms of the silicon surface turn into the dangling bonds, a considerable quantity of surface state is generated. For instance, 6.8×10¹⁴ atoms/cm² exit on a (100) plane. If 1/1,000 of them exist as dangling bonds, electric charge density trapped in a dangling bond interface can reach 6.8×10¹¹ atoms/cm².

The surface state can trap or emit the electric charges and forms an energy state within a forbidden band. Hence, like the aforesaid crystalline defect of the STI interface, the surface state causes the leakage that degrades the dark characteristics of the CMOS image sensor.

A variation of a dark signal is observed by increasing P+ type ion implantation and dose on a surface of an N− doped photodiode region for the reduction of the surface dangling bond effect.

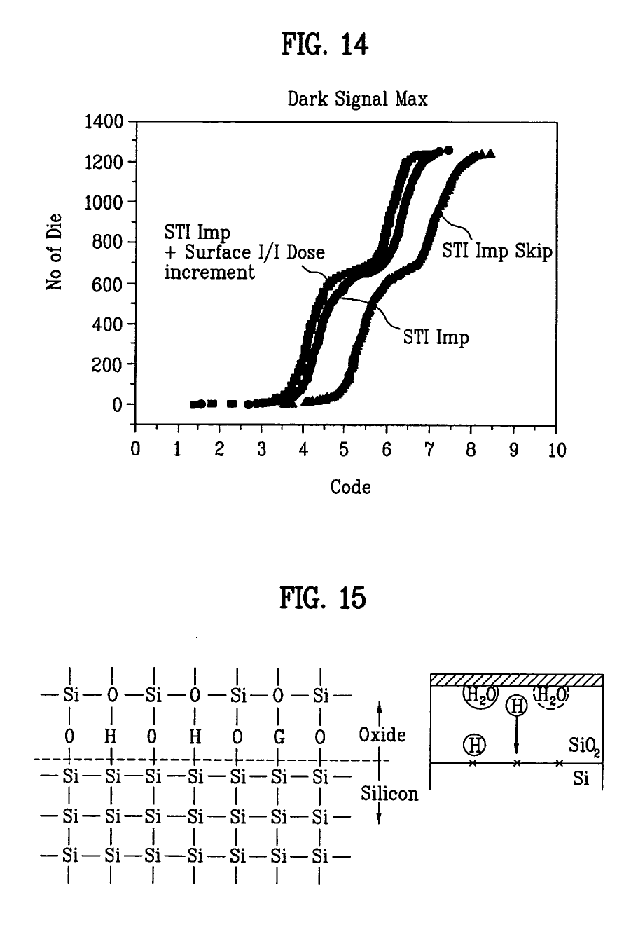

FIG. 14 is a graph of a variation of a dark signal following a photodiode surface ion implantation dose according to the present invention.

Referring to FIG. 14, if P+ doping is carried out on a photodiode surface, the dark characteristics of the image sensor are enhanced. And, the enhancement effect depends on the P+ doping density.

This is because a depletion area width extending toward a silicon surface according to the increment of the P+ doped density in a P+/N junction formed on the silicon surface. Like isolating an image sensing area from an STI lateral side, by increasing the P+density of the silicon surface, the dangling bond effect is reduced.

Instead of isolating the image sensing area from the dangling bonds by increasing the P+ doped density of the silicon surface, the dangling bonds can be reduced in a following proposed manner.

First of all, in an annealing process at a hydrogen ambience of 100% H₂ or 4%-H₂ formation gas, hydrogen atoms penetrate SiO₂ to be combined with dangling bonds. Hence, a process using an H₂ stream among subsequent processes of post metal anneal, BPSG reflow, silicon nitride deposition and the like needs to be optimized.

FIG. 15 is a diagram of dangling bond passivation and interface trap density reduction by hydrogen atoms on a silicon surface according to the present invention.

Referring to FIG. 15, hydrogen atoms penetrate SiO₂ to be combined with dangling bonds on a Si/SiO₂ interface, whereby the number of the dangling bonds is lowered.

Alternatively, the number of the dangling bonds can be lowered in a manner of selecting an appropriate wafer. A wafer used for fabricating a CMOS image sensor is an EPI wafer. In particular, a 0°-tilted wafer or a 4°-tilted wafer is advantageous in dangling bond reduction.

Moreover, a process-dependent surface damage reduction should be preceded.

Ion damage, as shown in FIG. 13, may be caused to a photodiode surface in performing plasma etch. Hence, a low damage condition is required for performing gate poly and gate spacer RIE that causes ion bombarding to an entire pixel.

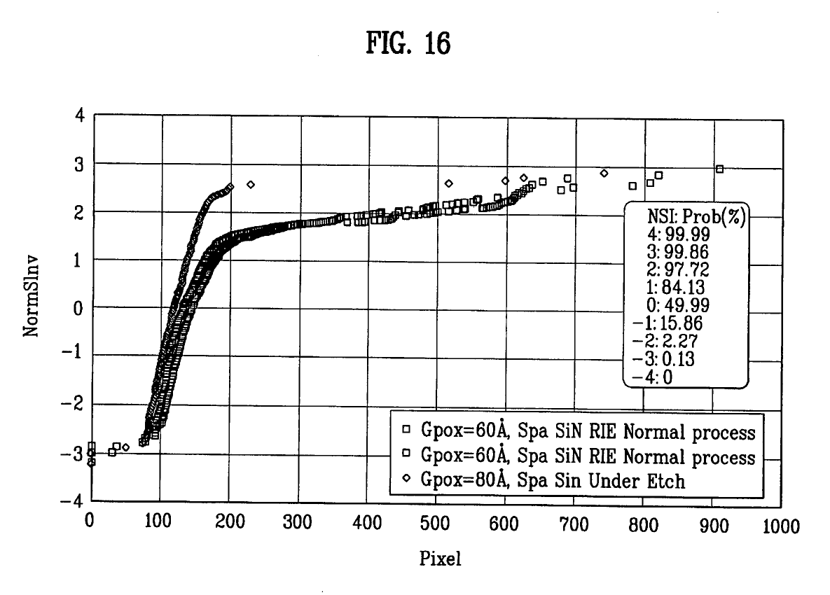

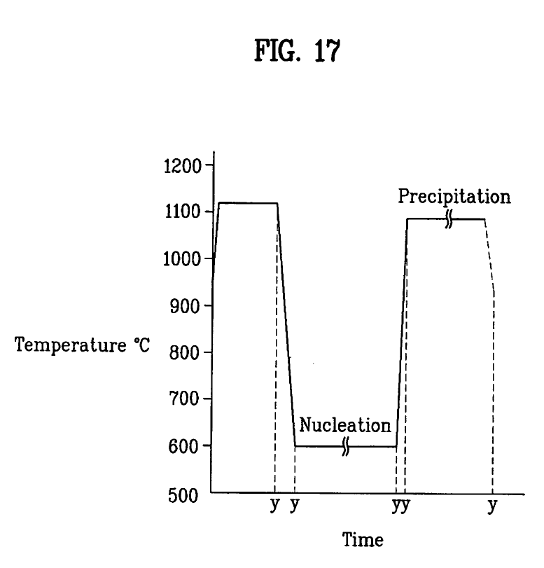

FIG. 16 is a graph of a dark defect variation due to gate sidewall oxidation and gate spacer under-etch according to the present invention.

Referring to FIG. 16, by tuning the gate sidewall oxidation and gate spacer RIE processes, the gate sidewall oxide thickness is increased. And, the gate spacer is under-etched to considerably lower the number of pixels having the dark defect 100 code or higher.

Fourthly, bulk defects within a wafer can be reduced in the following manner.

Over-saturated oxygen within a silicon wafer precipitates in thermal processing to form a cluster. The cluster grows to a larger precipitate to arouse stress. And, the stress can be released by forming a dislocation loop. The dislocation loop is operative as a place where impurity is trapped or localized. Through an effective intrinsic gettering process, the precipitates need to be formed on a periphery of an Epi layer corresponding to an image area. It has been reported that the intrinsic gettering can be achieved through a series of temperature cycles.

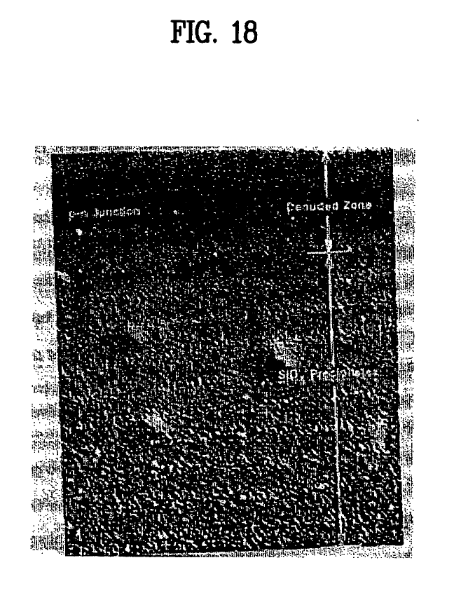

FIG. 17 is a graph of a thermal cycle for forming a denuded zone according to the present invention and FIG. 18 is a SEM picture of the denuded zone and SiOₓ precipitate generated from the thermal cycle in FIG. 17.

Oxygen density in the vicinity of a wafer surface is reduced through an initial high-temperature treatment, nucleuses are uniformly generated from a SiOₓ precipitation region through a low-temperature treatment, and SiOₓ nucleuses are then grown through final high-temperature treatment. Hence, the dislocation loop grows in a sector not affecting device characteristics considerably.

For the reduction of bulk defect of an Epi layer of a CMOS image sensor, it may be necessary to consider a denuded zone in selecting a wafer or optimizing annealing before/after an Epi layer process through a co-work with a wafer vender.

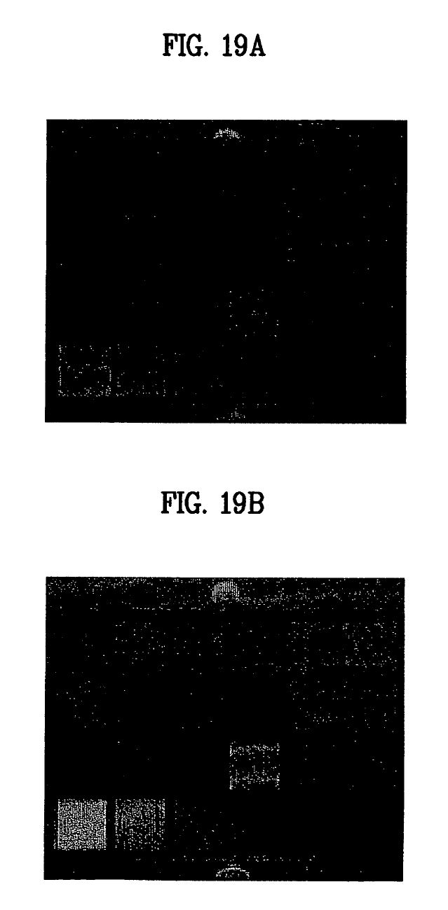

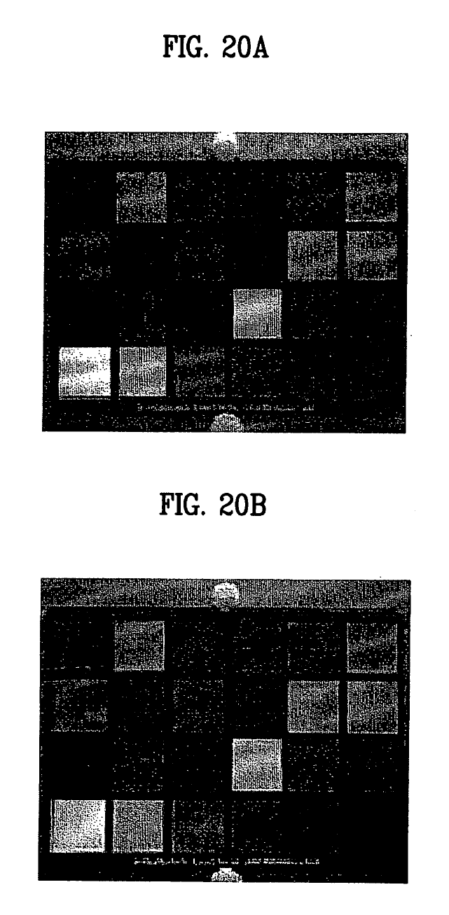

FIG. 19A and FIG. 19B are 10-lux and 160-lux images of a CMOS image sensor according to a related art, respectively, and FIG. 20A and FIG. 20B are 10-lux and 160-lux images of a CMOS image sensor according to the present invention, respectively.

Through the present invention, it can be confirmed that the image at 160 lux is enhanced as well as a low illumination intensity image measured at 10 lux.

Accordingly, the present invention provides the following effect.

First of all, by isolating the STI sidewall and the silicon surface, which are the crystalline defect areas, from the N type photodiode region, the reverse narrow width effect can be suppressed and the off-state characteristic can be enhanced.

Therefore, the dark characteristics of the CMOS image sensor can be enhanced.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A CMOS image sensor comprising:
a first conductive type semiconductor substrate divided into an active area and a field area;
an STI layer formed in the field area to divide the first conductive type semiconductor substrate into active area and the field area;
a second conductive type photodiode region formed in the active area of the first conductive type semiconductor substrate;
a readout circuit formed in the active area of the first conductive type semiconductor substrate to read out data of the photodiode regions; and
a first conductive type well formed between the second conductive type photodiode region and the STI layer.

2. The CMOS image sensor of claim 1, wherein the first conductive type semiconductor substrate comprises an epitaxial wafer having either a 0° or 4° tilt.

3. The CMOS image sensor of claim 1, further comprising a first conductive type heavily doped layer on a surface of the second conductive type photodiode regions.

4. A CMOS image sensor comprising:
a first conductive type semiconductor substrate divided into an active area and a field area;
an STI layer formed in the field area to divide the first conductive type semiconductor substrate into active area and the field area;
a second conductive type photodiode region formed in the active area of the first conductive type semiconductor substrate;
a readout circuit formed in the active area of the first conductive type semiconductor substrate to read out data of the photodiode regions; and
a first conductive type well formed between the STI layer and the active area of the first conductive semiconductor substrate.

5. The CMOS image sensor of claim 4, wherein the first conductive type semiconductor substrate comprises an epitaxial wafer having either a 0° or 4° tilt.

6. The CMOS image sensor of claim 4, further comprising a first conductive type heavily doped layer on a surface of the second conductive type photodiode regions.

7. A method of fabricating a CMOS image sensor, comprising the steps of:
forming a trench in a field area of a first conductive type semiconductor substrate wherein an active area and the field area are defined on the first conductive type semiconductor substrate and wherein a photodiode region and a readout circuit region to read out data of the photodiode region are defined in the active area;
forming a first conductive type well by implanting a first conductive type impurity into the trench neighboring the photodiode region; and
forming an STI layer by filling the trench with an insulating layer.

8. A method of fabricating a CMOS image sensor, comprising the steps of:
forming a trench in a field area of a first conductive type semiconductor substrate wherein an active area and the field area are defined on the first conductive type semiconductor substrate and wherein a photodiode region and a readout circuit region to read out data of the photodiode region are defined in the active area;
forming a first conductive type well by implanting a first conductive type impurity into the trench in the vicinity of the active area; and
forming an STI layer by filling the trench with an insulating layer.

9. A method of fabricating a CMOS image sensor, comprising the steps of:
preparing a first conductive type semiconductor substrate wherein an active area and a field area are defined on the first conductive type semiconductor substrate and wherein a photodiode region and a readout circuit region to read out data of the photodiode region are defined in the active area;
forming a trench in the field area;
forming a first conductive type well by implanting a first conductive type impurity into the trench in the vicinity of the active area;
forming an STI layer by filling the trench with an insulating layer;
implanting a second conductive type impurity into the photodiode region; and
heavily implanting the first conductive type impurity into a surface of the photodiode region implanted with the second conductive type impurity.
